(19) United States
(12) Patent Application Publication
(10) Pub. No.: US 2023/0064469 A1
(43) Pub. Date: Mar. 2, 2023

(54) WAFER, SEMICONDUCTOR DEVICE, METHOD FOR MANUFACTURING WAFER, AND METHOD FOR MANUFACTURING SEMICONDUCTOR DEVICE

(71) Applicant: KABUSHIKI KAISHA TOSHIBA, Tokyo (JP)

(72) Inventors: Mitsuhiro KUSHIBE, Setagaya (JP); Johji NISHIO, Machida (JP); Ryosuke IIJIMA, Setagaya (JP); Tatsuo SHIMIZU, Shinagawa (JP); Chiharu OTA, Kawasaki (JP); Shoko SUYAMA, Kawasaki (JP)

(73) Assignee: KABUSHIKI KAISHA TOSHIBA, Tokyo (JP)

(21) Appl. No.: 17/590,978

(22) Filed: Feb. 2, 2022

(30) Foreign Application Priority Data
Aug. 31, 2021 (JP) 2021-141053

(51) Int. Cl. H01L 29/16; C30B 29/36; H01L 21/02

(52) U.S. Cl. CPC H01L 29/1608; C30B 29/36; H01L 21/02378; H01L 21/02447

(57) ABSTRACT

According to one embodiment, a wafer includes a substrate and a crystal layer. The substrate includes a plurality of SiC regions including SiC and an inter-SiC region including Si provided between the SiC regions. The crystal layer includes a first layer, and a first intermediate layer provided between the substrate and the first layer in a first direction. The first layer includes SiC and nitrogen. The first intermediate layer includes SiC and nitrogen. A second concentration of nitrogen in the first intermediate layer is higher than a first concentration of nitrogen in the first layer.

### CROSS-REFERENCE TO RELATED APPLICATIONS

This application is based upon and claims the benefit of priority from Japanese Patent Application No. 2021-141053, filed on Aug. 31, 2021; the entire contents of which are incorporated herein by reference.

### FIELD

Embodiments described herein relate generally to a wafer, a semiconductor device, a method for manufacturing a wafer, and a method for manufacturing a semiconductor device.

### BACKGROUND

It is desired to improve the characteristics of wafers used in manufacturing semiconductor devices.

### BRIEF DESCRIPTION OF THE DRAWINGS

FIGS. 1A and 1B are schematic cross-sectional views illustrating a wafer according to a first embodiment;

FIG. 2 is a graph illustrating the characteristics of the wafer;

FIGS. 3A and 3B are graphs illustrating the characteristics of the wafer;

FIGS. 4A and 4B are graphs illustrating the characteristics of the wafer.;

FIGS. 5A and 5B are graphs illustrating the characteristics of the wafer;

FIG. 6 is a graph illustrating the characteristics of the wafer;

FIGS. 7A and 7B are schematic cross-sectional views illustrating a wafer according to the first embodiment:

FIGS. 8A to 8C are schematic cross-sectional views illustrating a method for manufacturing a wafer according to a second embodiment;

FIGS. 9A to 9C are schematic cross-sectional views illustrating the method for manufacturing the wafer according to the second embodiment;

FIGS. 10A to 10C are schematic cross-sectional views illustrating the method for manufacturing the wafer according to the second embodiment;

FIGS. 11A to 11C are schematic cross-sectional views illustrating the method for manufacturing the wafer according to the second embodiment;

FIGS. 12A to 12C are schematic cross-sectional views illustrating the method for manufacturing the wafer according to the second embodiment;

FIG. 13 is a graph illustrating characteristics related to a manufacturing method according to the second embodiment;

FIGS. 14A to 14D are schematic cross-sectional views illustrating the method for manufacturing the semiconductor device according to the third embodiment;

FIGS. 15A to 15C are schematic cross-sectional views illustrating the method for manufacturing the semiconductor device according to the third embodiment;

FIG. 16 is a schematic cross-sectional view illustrating the semiconductor device according to a fourth embodiment;

FIG. 17 is a schematic cross-sectional view illustrating the semiconductor device according to the fourth embodiment;

FIG. 18 is a schematic cross-sectional view illustrating the semiconductor device according to the fourth embodiment;

FIG. 19 is a schematic cross-sectional view illustrating the semiconductor device according to the fourth embodiment;

FIG. 20 is a schematic cross-sectional view illustrating the semiconductor device according to the fourth embodiment; and

FIG. 21 is a schematic cross-sectional view illustrating the semiconductor device according to the fourth embodiment.

### DETAILED DESCRIPTION

According to one embodiment, a wafer includes a substrate and a crystal layer. The substrate includes a plurality of SiC regions including SiC and an inter-SiC region including Si provided between the SiC regions. The crystal layer includes a first layer, and a first intermediate layer provided between the substrate and the first layer in a first direction. The first layer includes SiC and nitrogen. The first intermediate layer includes SiC and nitrogen. A second concentration of nitrogen in the first intermediate layer is higher than a first concentration of nitrogen in the first layer.

According to one embodiment, a semiconductor device includes a first electrode electrically connected with the first intermediate layer obtained by removing at least a part of the substrate of the wafer described above, the first intermediate layer obtained by the removing the at least the part of the substrate, and the first layer.

According to one embodiment, a method for manufacturing a wafer is disclosed. The method can include forming a first layer. The first layer includes SiC and nitrogen on a first intermediate layer base body to be a first intermediate layer including SiC and nitrogen. A second concentration of nitrogen in the first intermediate layer base body is higher than a first concentration of nitrogen in the first layer. The first intermediate layer base body includes a first layered region and a second layered region. The first layered region is between the second layered region and the first layer. The method can include removing the second layered region, and bonding a remaining first layered region to a substrate. The substrate includes a plurality of SiC regions including SiC, and an inter-SiC region including Si provided between the SiC regions.

According to one embodiment, a method for manufacturing a semiconductor device is disclosed. The method can include introducing a first element into at least a part of the first layer of the wafer described above. The first element includes at least one selected from the group consisting of B, Al and Ga. The method can include performing a heat treatment at a temperature not less than 1600° C. after the introducing.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

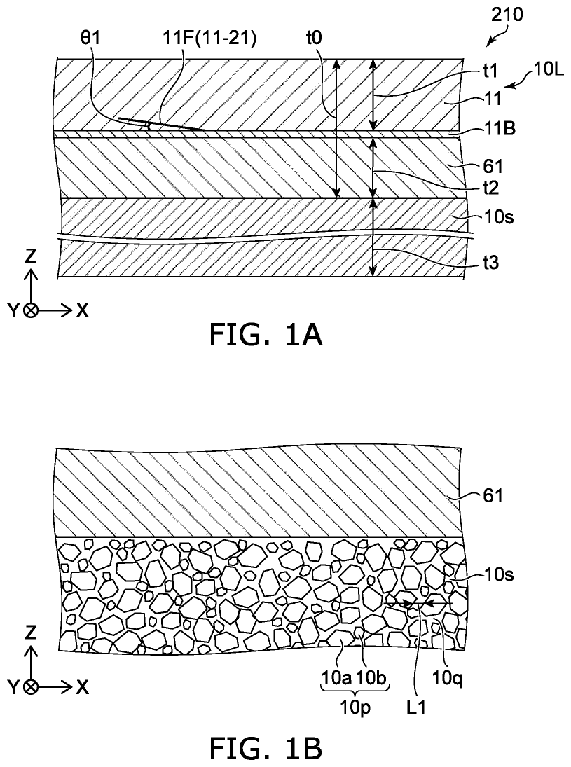

FIGS. 1A and 1B are schematic cross-sectional views illustrating a wafer according to the first embodiment.

FIG. 1B is an enlarged view of a part of FIG. 1A. As shown in FIG. 1A, a wafer 210 according to the embodiment includes a substrate 10s and a crystal layer 10L. The crystal layer 10L includes a first layer 11 and a first intermediate layer 61. For example, the crystal layer 10L is in contact with the substrate 10s.

The first intermediate layer 61 is provided between the substrate 10s and the first layer 11 in a first direction. As shown in FIG. 1A, the first direction from the first intermediate layer 61 to the first layer 11 is defined as a Z-axis direction. One direction perpendicular to the Z-axis direction is defined as an X-axis direction. The direction perpendicular to the Z-axis direction and the X-axis direction is defined as a Y-axis direction.

The substrate 10s spreads along the X-Y plane. The first intermediate layer 61 and the first layer 11 are, for example, along the X-Y plane. For example, the first intermediate layer 61 is in contact with the substrate 10s.

As shown in FIG. 1B, the substrate 10s includes a plurality of SiC regions 10p and an inter-SiC region 10q. The plurality of SiC regions 10p include SiC. The inter-SiC region 10q is provided between a plurality of SiC regions 10p. The inter-SiC region 10q includes Si. For example, the substrate 10s may be a sintered substrate including Si and Si-C. For example, Si is filled between a plurality of SiC regions 10p. The inter-SiC region 10q may be, for example, in the form of a network. The substrate 10s is, for example, a Si-impregnated SiC sintered substrate. Such a substrate 10s has excellent heat resistance. In such a substrate 10s, processing such as polishing or the like is easy.

In this example, the plurality of SiC regions 10p include a plurality of first SiC regions 10a and a plurality of second SiC regions 10b. The size of one of the plurality of first SiC regions 10a is larger than the size of one of the plurality of second SiC regions 10b. A size of the plurality of first SiC regions 10a may be, for example, a length along an arbitrary direction, for example, a diameter. A size of the plurality of second SiC regions 10b may be, for example, a length along an arbitrary direction, for example, a diameter. Substantially two or more peaks may be provided in the size distribution of the plurality of SiC regions 10p. Thereby, the gap between SiCs (the length of the inter-SiC region 10q) can be reduced. An average size (average diameter) of the plurality of first SiC regions 10a is, for example, not less than 1 μm and not more than 10 μm. An average size (average diameter) of the plurality of second SiC regions 10b is, for example, not less than 0.1 μm and less than 1 μm.

By the substrate 10s including the plurality of SiC regions 10p and the inter-SiC region 10q, the gap between the SiCs can be reduced. By the substrate 10s including the plurality of SiC regions 10p and the inter-SiC region 10q, the unevenness of the surface of the substrate 10s can be reduced. For example, it is easy to obtain a substantially flat surface.

The first layer 11 includes SiC. The first layer 11 includes nitrogen at a first concentration. By the first layer 11 including nitrogen, the first layer 11 functions as an n-type semiconductor layer. Nitrogen functions, for example, as an n-type impurity.

The first intermediate layer 61 includes SiC. A second concentration of nitrogen in the first intermediate layer 61 is higher than that the first concentration. For example, the first layer 11 is a low nitrogen concentration SiC layer. For example, the first intermediate layer 61 is a high nitrogen concentration SiC layer.

For example, the first intermediate layer 61 includes a SiC single crystal. For example, the first intermediate layer 61 is a hexagonal SiC single crystal layer. The first layer 11 includes a SiC single crystal. The first layer 11 is a SiC single crystal layer. The first layer 11 functions, for example, as at least a part of the functional layer of the semiconductor device.

A thickness of the substrate 10s is sufficiently thicker than a thickness of the crystal layer 10L. The crystal layer 10L is supported by the substrate 10s being thick.

For example, heat treatment is performed when the first layer 11 or the like provided on the substrate 10s is processed to form a semiconductor device. There is a difference in the coefficient of thermal expansion between the substrate 10s and the first layer 11. Due to the difference in the coefficient of thermal expansion, stress is generated in the substrate 10s and the crystal layer 10L. As described above, the substrate 10s is sufficiently thicker than the crystal layer 10L. Therefore, when the first intermediate layer 61 is not provided between the substrate 10s and the first layer 11, the generated stress is applied to the crystal layer 10L, and the crystal layer 10L is easily damaged. In the crystal layer 10L, for example, dislocations increase and the crystal quality of the crystal layer 10L deteriorates. This makes it difficult to obtain the desired characteristics.

In the embodiment, the first intermediate layer 61 is provided between the substrate 10s and the first layer 11. The concentration of nitrogen in the first intermediate layer 61 is higher than the concentration of nitrogen in the first layer 11. The lattice length of the first intermediate layer 61 having a high nitrogen concentration is shorter than the lattice length of the first layer 11 having a low nitrogen concentration. Stress is generated in the crystal layer 10L based on the difference in lattice length. The direction of stress based on the difference in lattice length is opposite to the direction of stress due to the difference in coefficient of thermal expansion between the substrate 10s and the crystal layer 10L. The stress due to the difference in the coefficient of thermal expansion can be reduced by the stress based on the difference in the lattice length. As a result, dislocations are suppressed, and a crystal layer 10L having high crystal quality can be obtained. For example, the first layer 11 having good characteristics can be obtained. According to the embodiment, it is possible to provide a wafer whose characteristics can be improved.

As shown in FIG. 1A, an intermediate region 11B may be provided. The intermediate region 11B is provided between the first intermediate layer 61 and the first layer 11. The nitrogen concentration in the intermediate region 11B is between the nitrogen concentration in the first intermediate layer 61 (second concentration) and the nitrogen concentration in the first layer 11 (first concentration). The intermediate region 11B is, for example, a transition layer. The intermediate region 11B is thinner than the first intermediate layer 61 and the first layer 11. Therefore, the influence of the intermediate region 11B on the stress can be substantially ignored.

For example, the second concentration is preferably not less than 5 times the first concentration. As a result, stress based on the difference in lattice length can be effectively generated in the crystal layer 10L. Thereby, the stress caused by the above-mentioned coefficient of thermal expansion can be effectively suppressed. The second concentration may be not less than 50,000 times the first concentration. For example, if the first concentration becomes excessively low, it becomes difficult to obtain good electrical characteristics in a semiconductor device manufactured from the wafer.

The nitrogen concentration in the first layer 11 (first concentration) is, for example, not less than 1×10¹⁵ cm⁻³ and mot more than 2×10¹⁷ cm⁻³. When the first concentration is not less than 1×10¹⁵ cm⁻³, good electrical characteristics can be easily obtained in, for example, a semiconductor device manufactured from the wafer. When the first concentration is not more than 2×10¹⁷ cm⁻³, it is easy to generate an appropriate stress in the crystal layer 10L including the first layer 11 and the first intermediate layer 61.

The concentration of nitrogen in the first intermediate layer 61 (second concentration) is, for example, not less than 1×10¹⁸ cm⁻³ and not more than 5×10¹⁹ cm⁻³. When the second concentration is not less than 1×10¹⁸ cm⁻³, it is easy to generate an appropriate stress in the crystal layer 10L. If the concentration of nitrogen in the first intermediate layer 61 becomes excessively high, for example, the crystal quality in the first intermediate layer 61 tends to deteriorate. When the second concentration is not more 5×10¹⁹ cm⁻³, high crystal quality can be maintained.

As shown in FIG. 1A, a thickness (length) of the first layer 11 along the first direction (Z-axis direction) from the first intermediate layer 61 to the first layer 11 is defined as the first thickness t1. A thickness (length) of the first intermediate layer 61 along the first direction is defined as the second thickness t2. In the embodiment, the first thickness t1 is preferably not less than 0.2 times and not more than 2 times the second thickness t2. For example, the first thickness t1 is not significantly different from the second thickness t2. This makes it easy to appropriately generate the desired stress in the crystal layer 10L due to the difference in nitrogen concentration.

In the embodiment, the first thickness t1 is preferably not less than 10 μm and not more than 80 μm. Good semiconductor characteristics can be easily obtained.

In the embodiment, the second thickness t2 is preferably not less than 10 μm and not more than 80 μm. Warpage is effectively suppressed. The second thickness t2 is more preferably not less than 20 μm and not more than 30 μm.

The substrate 10s has a third thickness t3 along the first direction (Z-axis direction). The crystal layer 10L has a thickness t0 along the first direction (Z-axis direction). The thickness t0 substantially corresponds to the sum of the first thickness t1 and the second thickness t2. The third thickness t3 is, for example, not less than 4 times the thickness t0. As a result, the substrate 10s is substantially not deformed and warpage is suppressed. The third thickness t3 may be, for example, not less than 5 times the thickness t0. The third thickness t3 may be, for example, not less than 10 times the thickness t0. The third thickness t3 may be, for example, not less than 50 times the thickness t0. For example, if the thickness of the crystal layer 10L becomes excessively thick, for example, internal stress such as thermal strain is generated in the substrate 10s, and warpage is likely to occur.

The third thickness t3 is preferably, for example, not less than 300 μm and not more than 800. Good handling can be obtained in the manufacturing method of semiconductor devices.

As shown in FIG. 1A, the first layer 11 has a (11-21) plane 11F. In the notation of “(11-21)” in the specification, the notation of “-” corresponds to “bar” for the number described after “-”. The notation of “(11-21)” follows the notation of the Miller index.

An angle between the (11-21) plane 11F and the X-Y plane in the first layer 11 is defined as an angle θ1. The angle θ1 corresponds to the offset angle. The X-Y plane is a plane perpendicular to a direction from the first intermediate layer 61 to the first layer 11 (the first direction and the Z-axis direction). In the embodiment, the angle θ1 may be not more than 4.5 degrees. Due to the offset, good crystallinity can be easily obtained in the crystal layer 10L. For example, when the angle θ1 exceeds 4.5 degrees, dislocations (BPD: Basal Plane Dislocation :) easily enter into a crystal layer epitaxially grown on the crystal layer 10L.

In the embodiment, for example, a basal plane dislocation density in the first intermediate layer 61 may be higher than a basal plane dislocation density in the first layer 11. As a result, the stress is more effectively relaxed in the first intermediate layer 61. The low dislocation density of the basal plane in the first layer 11 makes it easy to obtain good electrical characteristics in, for example, a semiconductor device obtained from the wafer.

The basal plane dislocation density in the first intermediate layer 61 is, for example, not less than 8×10¹ cm⁻² and not more than 1×10³ cm⁻². When the dislocation density of the basal plane in the first intermediate layer 61 is not less than 8×10¹ cm⁻², for example, stress is likely to be effectively relieved. When the basal plane dislocation density in the first intermediate layer 61 exceeds 1×10³ cm⁻², for example, the basal plane dislocation density in the first layer 11 tends to increase. The dislocation density of the basal plane in the first intermediate layer 61 may be, for example, not less than 1.5×10² cm⁻².

The basal plane dislocation density in the first layer 11 is preferably not more than 1 cm⁻², for example. Thereby, for example, in a semiconductor device obtained from the wafer, good electrical characteristics can be easily obtained.

For example, in the first layer 11, the basal plane dislocation is converted into a threading edge dislocation. For example, when the offset angle (the above angle θ1) is not more than 4.5 degrees, high conversion efficiency to threading edge dislocations can be obtained. Good electrical characteristics can be obtained in semiconductor devices.

Hereinafter, simulation results of an example of the stress generated in the crystal layer 10L will be described. In the simulation model, the crystal layer 10L is not fixed to the substrate 10s. In this model, the lattice length changes based on the difference in nitrogen concentration, resulting in stress between the first layer 11 and the first intermediate layer 61. In this model in which the crystal layer 10L is not fixed to the bae body 10s, the crystal layer 10L is deformed (warped) due to the stress caused by the difference in nitrogen concentration. The curvature of this deformation corresponds to the stress that occurs. In the following, the curvature parameter is used as a parameter indicating the stress generated in the crystal layer 10L.

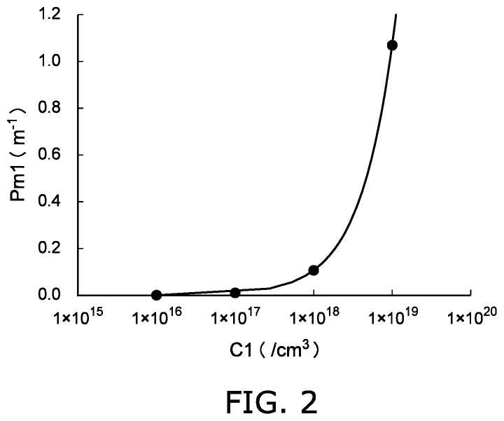

FIG. 2 is a graph illustrating the characteristics of the wafer.

The horizontal axis of FIG. 2 is the nitrogen concentration C1 in the first intermediate layer 61. The vertical axis is the curvature parameter Pm1. The curvature parameter Pm1 corresponds to the stress generated in the crystal layer 10L when the crystal layer 10L is not fixed to the substrate 10s as described above. When the curvature parameter Pm1 is high, the stress is large. In the example of FIG. 2, the concentration of nitrogen in the first layer 11 (first concentration) is 5×10¹⁵ cm⁻³. The first thickness t1 of the first layer 11 is the same as the second thickness t2 of the first intermediate layer 61.

As shown in FIG. 2, when the nitrogen concentration C1 (second concentration) in the first intermediate layer 61 increases, the curvature parameter Pm1 increases. In the region where the concentration C1 is not more than about 1×10¹⁷ cm⁻³, the increase in the curvature parameter Pm1 is slight, and the curvature parameter Pm1 does not change substantially. When the concentration C1 exceeds 1×10¹⁷ cm⁻³, the curvature parameter Pm1 increases significantly. When the concentration C1 is not less than 1×10¹⁸ cm⁻³, the curvature parameter Pm1 increases sharply.

In the embodiment, the concentration of the first intermediate layer is preferably not less than 1×10¹⁸ cm⁻³. As a result, a high curvature parameter Pm1 can be obtained. Stresses based on the difference in nitrogen concentration can be effectively obtained. Thereby, the deterioration of the crystal quality of the crystal layer 10L caused by the coefficient of thermal expansion can be effectively suppressed.

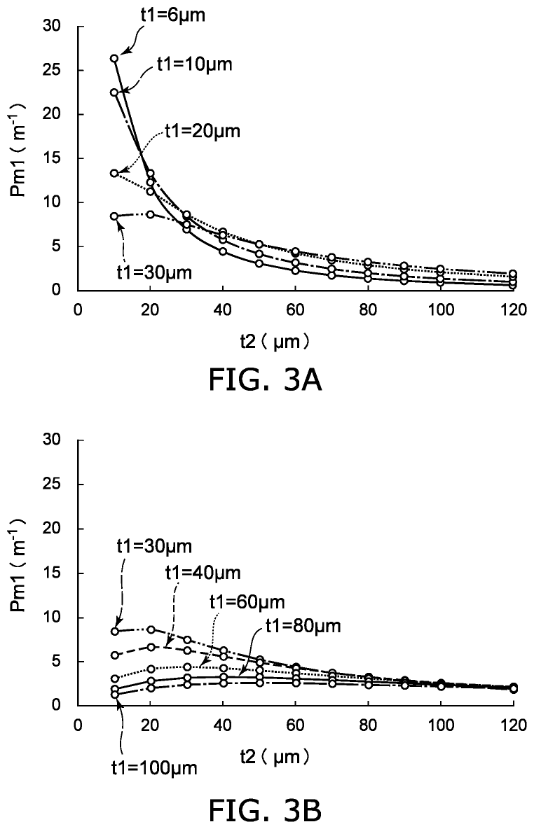

FIGS. 3A and 3B are graphs illustrating the characteristics of the wafer.

These figures exemplify the simulation results of the curvature parameter Pm1 corresponding to the stress when the first thickness t1 of the first layer 11 and the second thickness t2 of the first intermediate layer 61 are changed. Also in this case, in the simulation model, the crystal layer 10L is not fixed to the substrate 10s. In this example, the nitrogen concentration in the first layer 11 (first concentration) is 5×10¹⁵ cm⁻³, and the nitrogen concentration C1 (second concentration) in the first intermediate layer 61 is 5×10¹⁸ cm⁻³. The horizontal axis of these figures is the second thickness t2 of the first intermediate layer 61. The vertical axis of these figures is the curvature parameter Pm1. FIG. 3A corresponds to the characteristic that the first thickness t1 of the first layer 11 is 6 μm to 30 μm. FIG. 3B corresponds to the characteristic that the first thickness t1 of the first layer 11 is 30 μm to 100 μm. The first thickness t1 of the first layer 11 is changed in the range of 10 μm to 100 μm. The second thickness t2 of the first intermediate layer 61 is changed in the range of 10 μm to 120 μm.

As shown in FIGS. 3A and 3B, generally, when the first thickness t1 of the first layer 11 is thin and the second thickness t2 of the first intermediate layer 61 is thin, the parameter Pm1 being high is obtained. As shown in FIG. 3B, when the first thickness t1 is 30 μm to 120 μm, a peak is observed in the curvature parameter Pm1 when the second thickness t2 is changed. The second thickness t2 at which the curvature parameter Pm1 peaks becomes thinner as the first thickness t1 becomes thinner. As shown in FIG. 3A, no peak is observed in the curvature parameter Pm1 in the characteristics when the first thickness t1 is 6 μm to 20 μm. By analogy with the results of FIG. 3B, when the first thickness t1 is 6 μm to 20 μm, it is considered that the second thickness t2 at which the curvature parameter Pm1 peaks is not more than 10 μm.

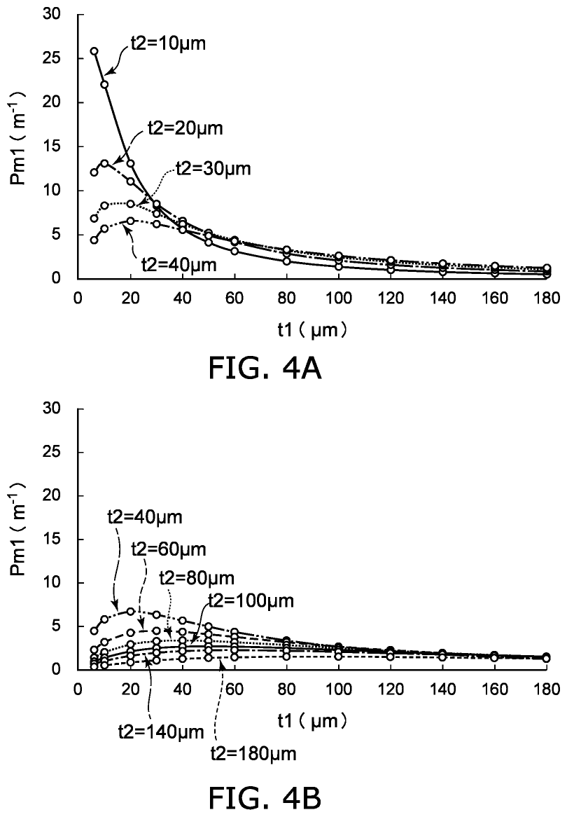

FIGS. 4A and 4B are graphs illustrating the characteristics of the wafer.

These figures illustrate the simulation results described with respect to FIGS. 3A and 3B with different axes. The horizontal axis of FIGS. 4A and 4B is the first thickness t1 of the first layer 11. The vertical axis of these figures is the curvature parameter Pm1. FIG. 4A corresponds to the characteristic that the second thickness t2 of the first intermediate layer 61 is 10 μm to 40 μm. FIG. 4B corresponds to the characteristic that the second thickness t2 of the first intermediate layer 61 is 40 μm to 180 μm.

As shown in FIGS. 4A and 4B, generally, when the first thickness t1 of the first layer 11 is thin and the second thickness t2 of the first intermediate layer 61 is thin, the parameter Pm1 being high is obtained. As shown in FIGS. 4A and 4B, when the second thickness t2 is 20 μm to 180 μm, a peak is observed in the curvature parameter Pm1 when the first thickness t1 is changed. The second thickness t2 at which the curvature parameter Pm1 peaks becomes thinner as the first thickness t1 becomes thinner. As shown in FIG. 4A, no peak is observed in the curvature parameter Pm1 in the characteristics when the second thickness t2 is 10 μm. By analogy with the result of FIG. 4B, when the second thickness t2 is 10 μm, it is considered that the first thickness t1 at which the curvature parameter Pm1 peaks is 10 μm or less.

As described above, there is a condition in which the curvature parameter Pm1 becomes the peak (maximum) in the combination of the first thickness t1 and the second thickness t2.

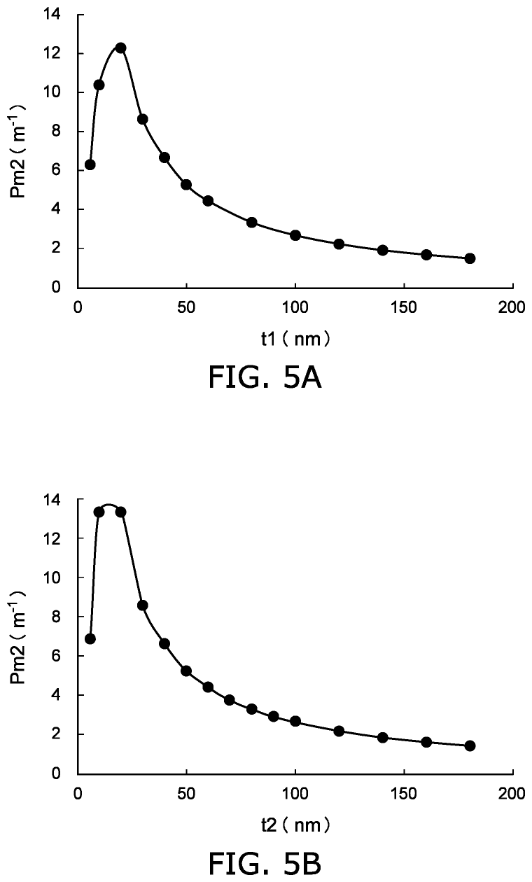

FIGS. 5A and 5B are graphs illustrating the characteristics of the wafer.

FIG. 5A illustrates the change in the highest value of the curvature parameter Pm1 obtained when the first thickness t1 is fixed in various combinations of the first thickness t1 of the first layer 11 and the second thickness t2 of the first intermediate layer 61. The horizontal axis of FIG. 5A is the first thickness t1 of the first layer 11. The vertical axis is the maximum value Pm2 of the curvature parameter Pm1.

As shown in FIG. 5A, when the first thickness t1 is larger than 80 μm, the maximum value Pm2 of the curvature parameter Pm1 is low. When the first thickness t1 is not more than 80 μm, the maximum value Pm2 of the curvature parameter Pm1 is high. When the first thickness t1 is not more than 80 μm, a high curvature parameter Pm1 can be obtained. When the first thickness t1 is not more than 80 μm and the first thickness t1 decreases, the maximum value Pm2 rises sharply. As shown in FIG. 5A, when the first thickness t1 is less than 10 μm, the maximum value decreases.

In the embodiment, the first thickness t1 is preferably not more than 80 μm. A high curvature parameter Pm1 (maximum value Pm2) is obtained. In the embodiment, the first thickness t1 is preferably not less than 10 μm. It is easy to obtain a high maximum value Pm2.

FIG. 5B illustrates the change in the highest value of the curvature parameter Pm1 obtained when the second thickness t2 is fixed in various combinations of the first thickness t1 of the first layer 11 and the second thickness t2 of the first intermediate layer 61. The horizontal axis of FIG. 5B is the second thickness t2 of the first intermediate layer 61. The vertical axis is the maximum value Pm2 of the curvature parameter Pm1.

As shown in FIG. 5B, when the second thickness t2 is larger than 80 μm, the maximum value Pm2 of the curvature parameter Pm1 is low. When the second thickness t2 is not more than 80 μm, the maximum value Pm2 of the curvature parameter Pm1 is high. When the second thickness t2 is not more than 80 μm, a high curvature parameter Pm1 can be obtained. When the second thickness t2 is not more than 80 μm and the first thickness t1 decreases, the maximum value Pm2 rises sharply. As shown in FIG. 5B, when the first thickness t1 is less than 10 μm, the maximum value decreases.

In the embodiment, the second thickness t2 is preferably not more than 80 μm. A high curvature parameter Pm1 (maximum value Pm2) is obtained. In the embodiment, the second thickness t2 is preferably not less than 10 μm. It is easy to obtain a high maximum value Pm2. The second thickness t2 may be not less than 20 μm. A high maximum value Pm2 is stably and easily obtained.

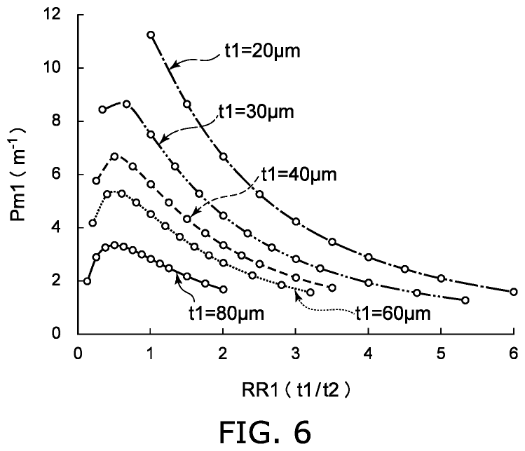

FIG. 6 is a graph illustrating the characteristics of the wafer. The horizontal axis of FIG. 6 is a thickness ratio RR1. The thickness ratio RR1 is a ratio of the first thickness t1 to the second thickness t2. The vertical axis of FIG. 6 is the curvature parameter Pm1.

As shown in FIG. 6, when the first thickness t1 is not less than 30 μm and not more than 80 μm, the curvature parameter Pm1 shows a peak when the thickness ratio RR1 changes. For the thickness of various combinations, the curvature parameter Pm1 is preferably high.

For example, in the range where the first thickness t1 is not less than 30 μm and not more than 80 μm, the thickness ratio RR1 at which the curvature parameter Pm1 peaks is in the range of not less than 0.4 and not more than 0.75. A high curvature parameter Pm1 (peak) can be obtained in the range where the thickness ratio RR1 is not less than 0.4 and not more than 0.75. Even at a thickness ratio RR1 lower than the thickness ratio RR1 at which the curvature parameter Pm1 peaks or a thickness ratio RR1 higher than the thickness ratio RR1, a somewhat high curvature parameter Pm1 can be obtained.

For example, the range up to ½ of the peak value of the curvature parameter Pm1 is defined as the “range of high curvature parameter Pm1”. The ratio RR1 at which this “range of high curvature parameter Pm1” can be obtained is about not less than 0.2 and not more than 2 when the first thickness t1 is not less than 30 μm and not more than 80 μm. At such a thickness ratio RR1, a high curvature parameter Pm1 can be obtained.

On the other hand, when the first thickness t1 is 20 μm, the curvature parameter Pm1 does not show a peak in the simulation result illustrated in FIG.6. When the first thickness t1 is 20 μm, the curvature parameter Pm1 decreases monotonically as the ratio RR1 increases. When the first thickness t1 is 20 μm, the value of the curvature parameter Pm1 is sufficiently high for any thickness ratio RR1. Therefore, even when the first thickness t1 is 20 μm, a high curvature parameter Pm1 can be obtained in the range where the ratio RR1 is not less than 0.2 and not more than 2.

In the embodiment, the thickness ratio RR1 is preferably not less than 0.2 and not more than 2. That is, the first thickness t1 of the first layer 11 along the first direction (Z-axis direction) is not less than 0.2 times and not more than 2 times the second thickness t2 of the first intermediate layer 61 along the first direction. As a result, a high curvature parameter Pm1 can be obtained. A large stress corresponding to the high curvature parameter Pm1 can be generated in the crystal layer 10L.

As shown in FIG. 6 and the like, the curvature parameter Pm1 can be 10 m⁻¹ or more. It is conceivable that the curvature parameter Pm1 becomes excessively high and the stress based on the difference in nitrogen concentration becomes excessively large. It is conceivable that the stress based on the difference in nitrogen concentration becomes excessively large, and its value becomes excessively large than the stress caused by the difference in the coefficient of thermal expansion between the substrate 10s and the crystal layer 10L. In this case, it is considered that defects may be generated in the crystal layer 10L due to the stress based on the difference in nitrogen concentration. However, the stress based on the difference in nitrogen concentration does not practically greatly exceed the absolute value of the stress due to the difference in the coefficient of thermal expansion. Therefore, in a practical range, it can be considered that the stress caused by the difference in the coefficient of thermal expansion can be relaxed by the high curvature parameter Pm1.

As shown in FIG. 1B, in the embodiment, the substrate 10s may include a plurality of inter-SiC regions 10q. The average length L1 of the plurality of inter-SiC regions 10q is preferably not more than 0.3 μm. The length L1 corresponds to the length of the inter-SiC region 10q along the direction perpendicular to the first direction (Z-axis direction). The length L1 may be, for example, a length in an arbitrary direction (for example, the X-axis direction) along the X-Y plane. The length L1 corresponds, for example, to the distance between the plurality of SiC regions 10p.

The length L1 being long corresponds to a large gap between the plurality of SiC regions 10p. When the average of the length L1 exceeds 0.3 μm, the unevenness on the surface of the substrate 10s becomes excessively large. In this case, the adhesion between the substrate 10s and the crystal layer 10L is reduced, and the crystal layer 10L is easily peeled off from the substrate 10s by, for example, high temperature treatment. When the average of the length L1 is not more than 0.3 μm, peeling can be suppressed. When the average length L1 is not more than 0.3 μm, the surface unevenness of the substrate 10s can be reduced.

In the embodiment, the inter-SiC region 10q includes Si. For example, the gap between the plurality of SiC regions 10p is filled with Si. It is possible to suppress the formation of voids between the plurality of SiC regions 10p. When a void is generated, a liquid or a gas or the like enters the void in the process of manufacturing a semiconductor device using a wafer, which tends to interfere with a desired process. Voids can be suppressed by including Si in the inter-SiC region 10q. As a result, it is possible to stably manufacture a semiconductor device using the wafer.

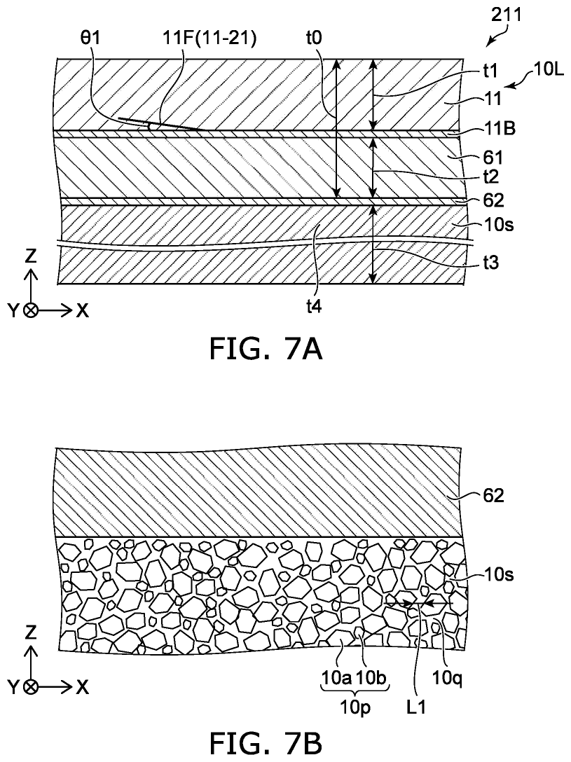

FIGS. 7A and 7B are schematic cross-sectional views illustrating a wafer according to the first embodiment.

FIG. 7B is an enlarged view of a part of FIG. 7A. As shown in FIG. 7A, a wafer 211 according to the embodiment includes the substrate 10s, the first layer 11, the first intermediate layer 61, and the second intermediate layer 62. In the wafer 211, the configuration excluding the second intermediate layer 62 may be the same as the configuration of the wafer 210.

The second intermediate layer 62 is provided between the substrate 10s and the first intermediate layer 61. The second intermediate layer 62 includes SiC. A concentration of nitrogen in the second intermediate layer 62 is higher than the second concentration of nitrogen in the first intermediate layer 61. As a result, in the crystal layer 10L, the stress based on the difference in nitrogen concentration can be increased more stably. As a result, the stress caused by the difference in the coefficient of thermal expansion can be relaxed more stably. It is easy to obtain a higher quality crystal layer 10L.

The second intermediate layer 62 is, for example, an incomplete SiC layer having a high nitrogen concentration. The concentration of nitrogen in the second intermediate layer 62 is, for example, not less than 1×10¹⁹ cm⁻³ and not more than 3×10²⁰ cm⁻³. The thickness of the second intermediate layer 62 (fourth thickness t4) is, for example, not less than 0.5 μm and not more than 3 μm.

In the substrate 10s according to the embodiment, it is preferable that at least a part of the plurality of SiC regions 10p is in the a phase. As a result, phase change is unlikely to occur even in heat treatment at a high temperature (for example, not less than 1600° C.).

Hereinafter, an example of a method for manufacturing the wafer according to the embodiment will be described.

### Second Embodiment

The second embodiment relates to a method for manufacturing the wafer.

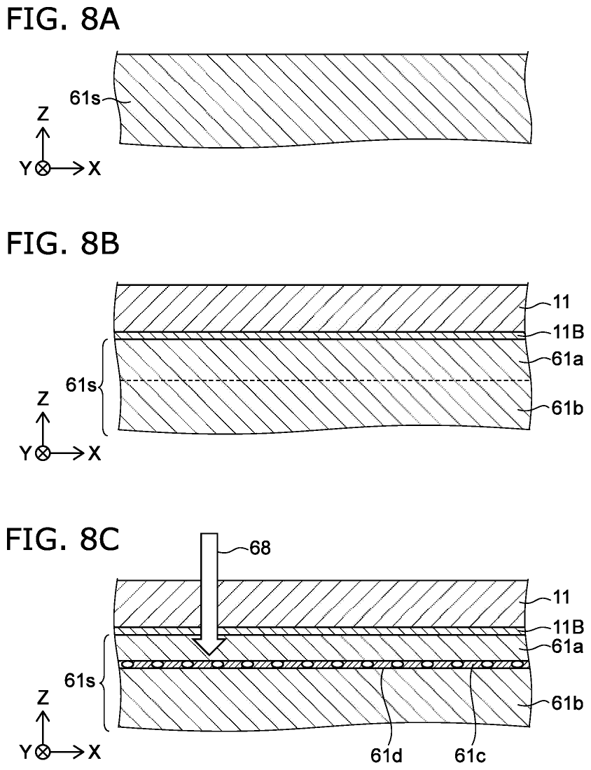

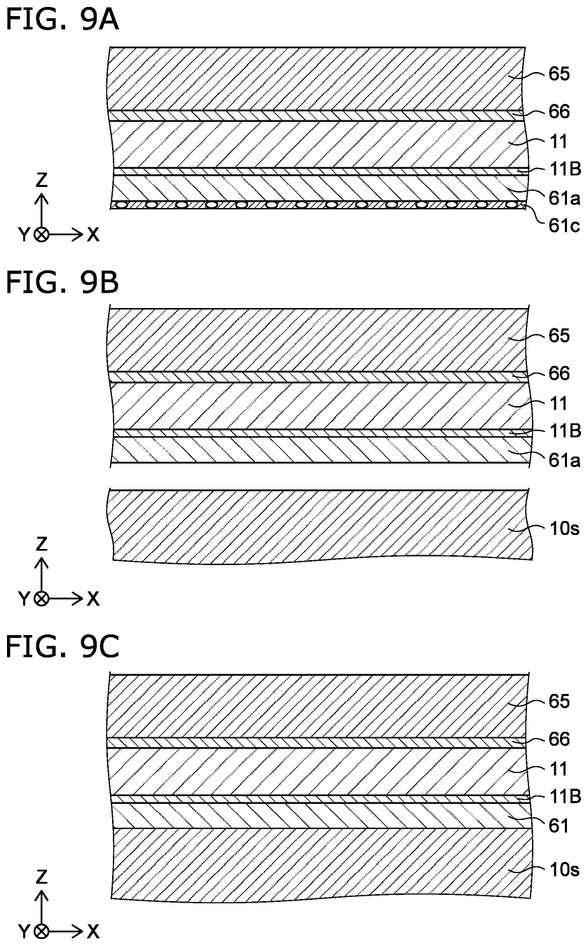

FIGS. 8A to 8C and 9A to 9C are schematic cross-sectional views illustrating the method for manufacturing the wafer according to the second embodiment.

As shown in FIG. 8A, the first intermediate layer base body 61s is prepared. The first intermediate layer base body 61s becomes the first intermediate layer 61 including SiC. The first intermediate layer base body 61s includes SiC. The concentration of nitrogen in the first intermediate layer base body 61s is not less than 3×10¹⁸ cm⁻³. The basal plane dislocation density in the first intermediate layer base body 61s is, for example, not less than 1.5×10² cm⁻². The first intermediate layer base body 61s is, for example, a SiC single crystal substrate.

As shown in FIG. 8B, the first layer 11 is formed on the first intermediate layer base body 61s. The first layer 11 includes SiC. The first layer 11 can be formed by, for example, epitaxial growth. The first layer 11 includes nitrogen at the first concentration. As described above, the concentration of nitrogen in the first intermediate layer base body 61s (for example, second concentration) is higher than the first concentration.

As shown in FIG. 8B, in one example, the intermediate region 11B may be provided between the first intermediate layer base body 61s and the first layer 11.

As shown in FIG. 8C, the first intermediate layer base body 61s includes a first layered region 61a and a second layered region 61b. The first layered region 61a is between the second layered region 61b and the first layer 11. The first layered region 61a is a region close to the first layer 11. The second layered region 61b is a region far from the first layer 11. In the state illustrated in FIG. 8C, the boundaries of these layered regions may be unclear.

As shown in FIG. 8C, after the formation of the first layer 11, the third layered region 61c is formed between the first layered region 61a and the second layered region 61b. For example, the first intermediate layer base body 61s is irradiated with an electromagnetic wave 68. The electromagnetic wave 68 is, for example, a laser light. The wavelength (center wavelength) of the laser light is, for example, not less than 390 nm and not more than 1200 nm. The power of the laser light is, for example, not less than 30 mW and not more than 30 W.

As shown in FIG. 8C, a modified region 61d is formed in the third layered region 61c by irradiation with the electromagnetic wave 68 (laser light). In the modified region 61d, the mechanical strength is locally reduced. Thus, the formation of the third layered region 61c may include irradiating the first intermediate layer base body 61s with the electromagnetic wave 68. As a result, the third layered region 61c is formed. The third layered region 61c is, for example, a crushed layer. The mechanical strength of the third layered region 61c is lower than that of the other regions (first layered region 61a and second layered region 61b). For example, the crystallinity in the third layered region 61c is lower than the crystallinity in the first layered region 61a. The crystallinity in the third layered region 61c is lower than the crystallinity in the second layered region 61b. Information on crystallinity in these layers can be obtained, for example, by X-ray diffraction analysis. For example, when the crystallinity is low, the peak of the intensity obtained by X-ray diffraction becomes broad.

When the third layered region 61c (for example, the modified region 61d) is formed by irradiation with the electromagnetic wave 68 (laser light), peeling occurs between the first layered region 61a and the second layered region 61b from the portion where the modified region 61d is formed. As a result, the second layered region 61b is removed (see FIG. 9A). Thus, the removing the second layered region 61b includes forming the third layered region 61c between the first layered region 61a and the second layered region 61b after the formation of the first layer 11.

As shown in FIG. 9B, the workpiece from which the second layered region 61b has been removed is opposed to the base body 10s. For example, the first layered region 61a being remained faces the substrate 10s.

As shown in FIG. 9C, the first layered region 61a being remained is bonded to the substrate 10s. The substrate 10s has the configuration described with respect to the first embodiment. As illustrated in FIG. 1B, the substrate 10s includes a plurality of SiC regions 10p including SiC and an inter-SiC region 10q provided between the plurality of SiC regions 10p and including Si. The first layered region 61a being remained becomes the first intermediate layer 61.

In the bonding, for example, direct bonding is performed. The direct bonding is performed in a reduced pressure atmosphere (less than 1 atm). Prior to the bonding, the surface of the first layered region 61a may be flattened. Prior to the bonding, the surface of the substrate 10s may be flattened. At the time of the bonding, Ar or the like may be introduced into the space between the first layered region 61a and the substrate 10s. As a result, spatter cleaning is performed. At the time of the bonding, Si may be deposited on at least one of the surfaces of the first layered region 61a and the surface of the substrate 10s.

By the above processing, the wafer 210 according to the embodiment can be obtained.

As will be described later, the third layered region 61c may remain after the removing the second layered region 61b. Prior to the bonding, the third layered region 61c may be removed. Further, as described above, a part (surface portion) of the first layered region 61a being remained may be removed and flattened. As described above, the method for manufacturing a wafer according to the embodiment further includes, removing a part of the first layered region 61b being remained and flattening after the removing the second layered region 61b and before the bonding.

As shown in FIG. 9A, a support member 65 (for example, a support substrate) may be fixed to the first layer 11 after the first layer 11 is formed. The support member 65 includes, for example, graphite. For example, a resin layer 66 is provided between the first layer 11 and the support member 65. The support member 65 is fixed to the first layer 11 by the resin layer 66. After the second layered region 61b is removed, the first layer 11 and the first layered region 61a are supported by the support member 65. The fixing the support member 65 to the first layer 11 may be performed in any technically possible step.

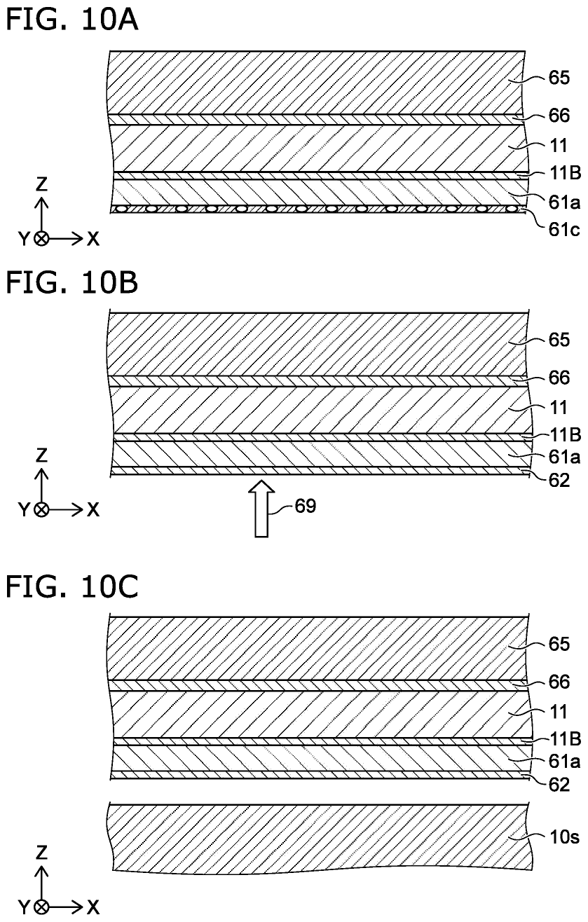

FIGS. 10A to 10C are schematic cross-sectional views illustrating the method for manufacturing the wafer according to the second embodiment.

As shown in FIG. 10A, after the step described with respect to FIG. 8C, the third layered region 61c remains after the removing the second layered region 61b. The third layered region 61c is removed. The removing can be performed by, for example, CMP (Chemical Mechanical Polishing) or the like.

As shown in FIG. 10B, for example, ions 69 are injected into a part (surface portion) of the first layered region 61a exposed by the removing the third layered region 61c. Ion 69 includes nitrogen. As a result, a region including nitrogen at a high concentration (second intermediate layer 62) is formed. The first layered region 61a being remained becomes the first intermediate layer 61.

As shown in FIG. 10C, the second intermediate layer 62 and the substrate 10s are opposed to each other. The second intermediate layer 62 and the substrate 10s are bonded. In the bonding, the above-mentioned direct bonding is performed. Thereby, for example, the wafer 211 according to the embodiment can be obtained.

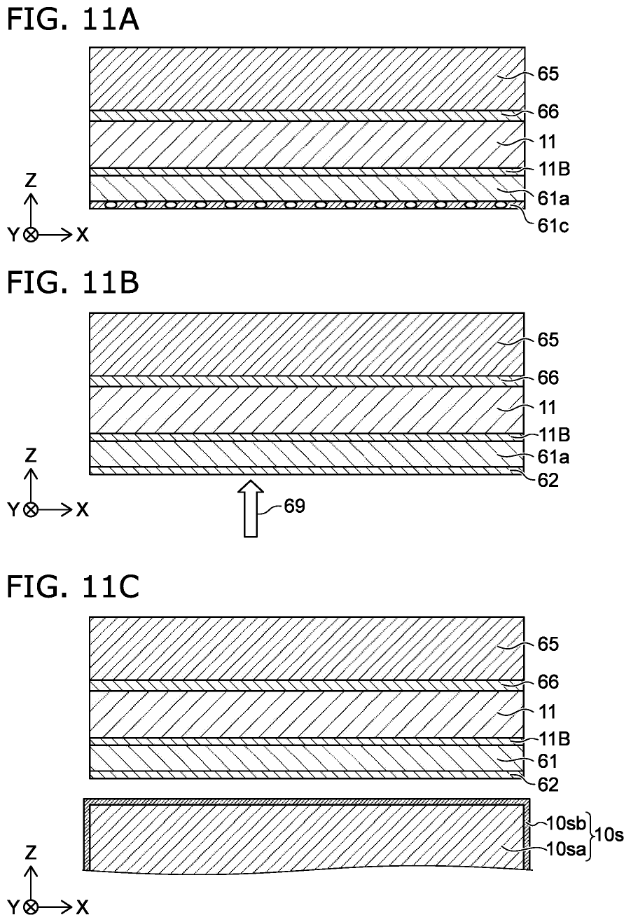

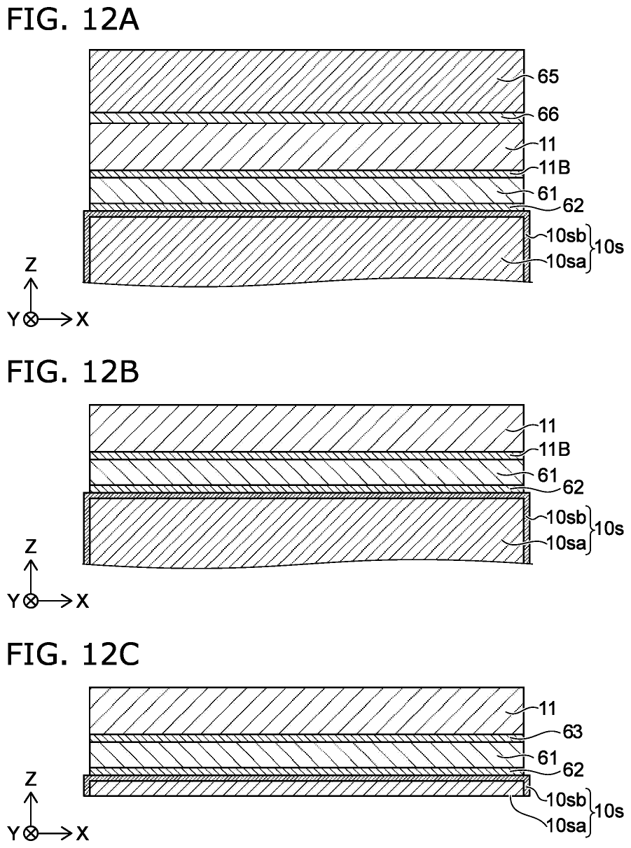

FIGS. 11A to 11C and 12A to 12C are schematic cross-sectional views illustrating the method for manufacturing the wafer according to the second embodiment.

As shown in FIGS. 11A and 11B, the third layered region 61c is removed and the second intermediate layer 62 is formed.

As shown in FIG. 11C, the substrate 10s is prepared. The substrate 10s includes a first substrate portion 10sa and a second substrate portion 10sb. The first substrate portion 10sa includes a plurality of SiC regions 10p and an inter-SiC region 10q (see FIG. 1B). The first substrate portion 10sa is, for example, a sintered substrate including Si and Si-C. The second substrate portion 10sb is provided on the surface of the first substrate portion 10sa. The second substrate portion 10sb includes, for example, polycrystalline SiC. The second substrate portion 10sb can be formed by, for example, CVD (Chemical Vapor Deposition) or the like. The thickness of the second substrate portion 10sb is, for example, not less than 0.1 μm and not more than 300 μm.

As shown in FIG. 11C, the second substrate portion 10sb of the substrate 10s is opposed to the second intermediate layer 62. As shown in FIG. 12A, the second intermediate layer 62 and the substrate 10s (second substrate portion 10sb) are bonded. In the bonding, the above-mentioned direct bonding is performed. Thereby, for example, the wafer according to the embodiment can be obtained. During and after the bonding, at least a part of the second substrate portion 10sb is located between at least a part of the first substrate portion 10sa and at least a part of the first layer 11. In this example, a portion of the second substrate portion 10sb is located between the first substrate portion 10sa and the second intermediate layer 62 during and after the bonding.

As shown in FIG. 12B, the resin layer 66 and the support member 65 are removed. For example, by removing the resin layer 66, the support member 65 is peeled off. The resin layer 66 and the support member 65 may be removed by polishing or the like.

As shown in FIG. 12C, at least a part of the first substrate portion 10sa may be removed to make the first substrate portion 10sa thinner. At this time, a corresponding portion of the second substrate portion 10sb is also removed. All of the first substrate portion 10sa may be removed. The second substrate portion 10sb may also be removed. In this way, the substrate 10s may be thinned. All of the substrate 10s may be removed.

The concentration of nitrogen in the second substrate portion 10sb may be higher than the concentration of nitrogen in the first intermediate layer 61 (second concentration). In this case, at least a part of the second substrate portion 10sb being remained may become at least a part of the second intermediate layer 62. In this case, the formation of the second intermediate layer 62 (for example, the introduction of ions 69) illustrated in FIG. 11B may be omitted.

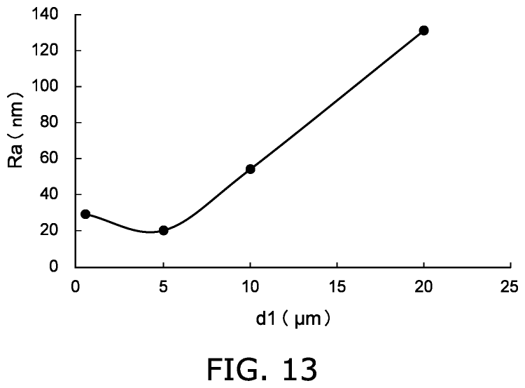

FIG. 13 is a graph illustrating the characteristics of the method according to the embodiment.

As described above, the surface of the substrate 10s may be flattened before bonding with the substrate 10s. The flattening may be performed by, for example, polishing with abrasive grains. The horizontal axis of FIG. 13 is the diameter d1 of the abrasive grains. The vertical axis is the surface roughness Ra of the substrate 10s after polishing with abrasive grains.

As shown in FIG. 13, in the range where the diameter d1 is not less than 5 μm, the surface roughness Ra decreases as the diameter d1 decreases. When the diameter d1 is smaller than 5 μm, the surface roughness Ra increases. This is because when the diameter d1 is excessively small, Si in the inter-SiC region 10q included in the substrate 10s is easily removed. As a result, it is considered that a plurality of SiC regions 10p remain and the surface roughness Ra of the substrate 10s becomes large. When the diameter d1 is not less than 5 μm, it is suppressed that the abrasive grains remove Si in the inter-SiC region 10q. Therefore, in the range where the diameter d1 is not less than 5 μm, it is preferable that the diameter d1 is small. As a result, the substrate 10s being flat can be obtained.

The diameter d1 of the abrasive grains is preferably larger than the average of the length L1 (see FIG. 1B) of the plurality of inter-SiC regions 10q. If the diameter d1 is excessively small, Si in a plurality of inter-SiC regions 10q is selectively removed, and the surface roughness Ra tends to increase. It is practically preferable that the diameter d1 is not less than 2 times the average of the length L1 (see FIG. 1B) of the plurality of inter-SiC regions 10q.

The method for manufacturing a wafer according to the embodiment may include polishing the substrate 10s with a plurality of abrasive grains before bonding the substrates 10s. The average diameter d1 of the plurality of abrasive grains is preferably not less than 0.5 μm. The substrate 10s being flat can be obtained.

### Third Embodiment

The third embodiment relates to a method for manufacturing a semiconductor device.

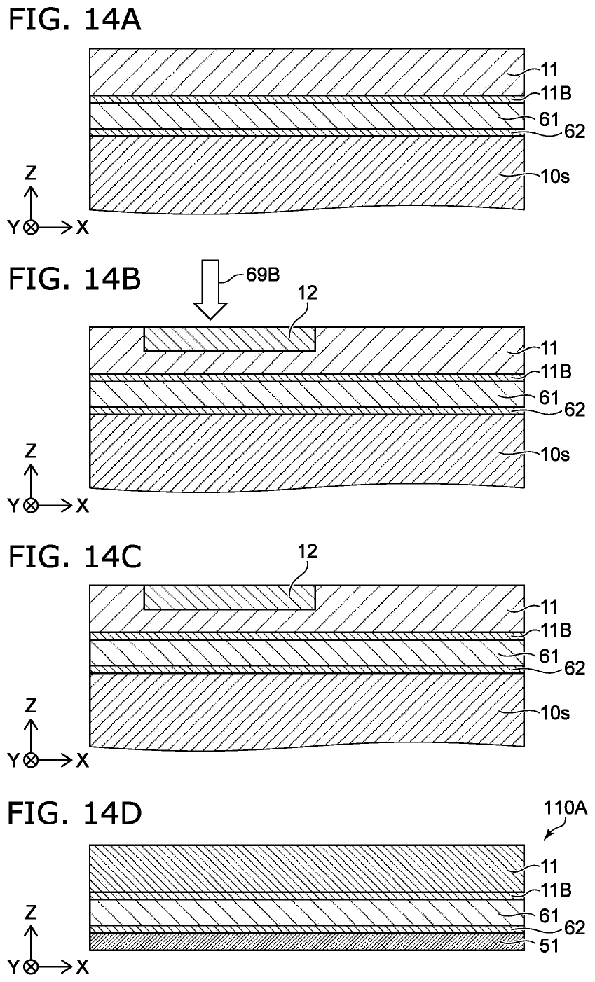

FIGS. 14A to 14D are schematic cross-sectional views illustrating the method for manufacturing the semiconductor device according to the third embodiment. As shown in FIG. 14A, a wafer (wafer 210, 211, etc.) according to the first embodiment is prepared. The substrate 10s may include a first substrate portion 10sa and a second substrate portion 10sb (see FIG. 12C and the like). The wafer may include a second intermediate layer 62 in addition to the first intermediate layer 61 and the first layer 11.

As shown in FIG. 14B, the first element 69B is introduced into at least a part of the first layer 11. The first element 69B includes at least one selected from the group consisting of B, Al and Ga. The first element 69B functions as a p-type impurity. A second semiconductor region 12 including the first element 69B is formed.

As shown in FIG. 14C, heat treatment is performed after the introducing the first element 69B. The heat treatment is a heat treatment at a temperature of not less than 1600° C. As a result, the first element 69B is activated. The second semiconductor region 12 functions as a target p-type semiconductor.

In the embodiment, the wafer includes the substrate 10s, the first intermediate layer 61, and the first layer 11. As a result, stress is relaxed even in high-temperature heat treatment, and warpage is suppressed. A semiconductor device using a wafer can be stably manufactured.

As shown in FIG. 14D, at least a part of the substrate 10s is removed after the heat treatment. As a result, the substrate 10s becomes thin. Alternatively, the entire substrate 10s may be removed. The first electrode 51 is formed on the surface exposed by removing at least a part of the substrate 10s. In this example, the first electrode 51 is in contact with the second intermediate layer 62. The first electrode 51 may be in contact with the first intermediate layer 61. As a result, the semiconductor device 110A is obtained.

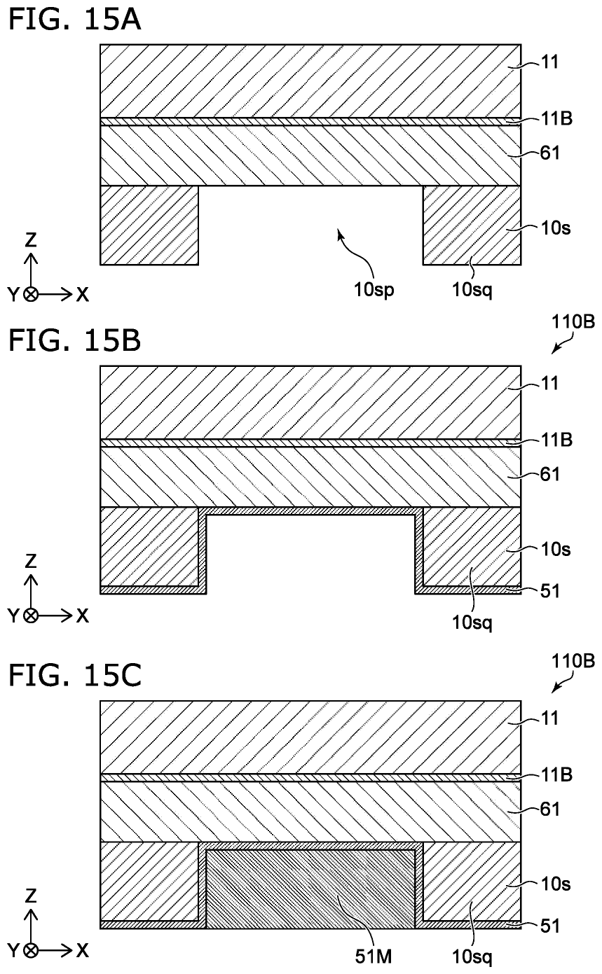

FIGS. 15A to 15C are schematic cross-sectional views illustrating the method for manufacturing the semiconductor device according to the third embodiment.

As shown in FIG. 15A, after the heat treatment (see FIG. 12C), a part 10sp of the substrate 10s is removed, leaving the other part 10sq of the substrate 10s. In the removing a part of 10sp of the substrate 10s, for example, etching using a mask material or the like is performed. The etching may include, for example, REI (Reactive Ion Etching). The etching may include wet etching. In this example, the substrate 10s may include the first substrate portion 10sa and the second substrate portion 10sb. In the etching, the first intermediate layer 61 (or the second intermediate layer 62) may function as an etching stopper.

As shown in FIG. 15B, the first electrode 51 is formed on the exposed surface by removing a part 10sp of the substrate 10s. The first electrode 51 is in contact with the exposed first intermediate layer 61 (or second intermediate layer 62). The first electrode 51 is in contact with the other part 10sq of the substrate 10s. The first electrode 51 is electrically connected with the first intermediate layer 61 (or the second intermediate layer 62). As a result, the semiconductor device 110B is obtained.

In this example, the first electrode 51 is electrically connected with the first intermediate layer 61 (or the second intermediate layer 62) without passing through the entire substrate 10s. Thereby, the resistance (ON-resistance) in the semiconductor device 110B can be lowered.

The semiconductor device 110B includes the other part 10sq of the substrate 10s. As a result, high mechanical strength can be obtained in the semiconductor device 110B.

As shown in FIG. 15C, a conductive material 51M may be formed in the space where the recess formed by removing a part of 10sp of the substrate 10s remains. The conductive material 51M is embedded in the recess. The depth of the recess is reduced. Higher mechanical strength is obtained.

### Fourth Embodiment

The fourth embodiment relates to a semiconductor device.

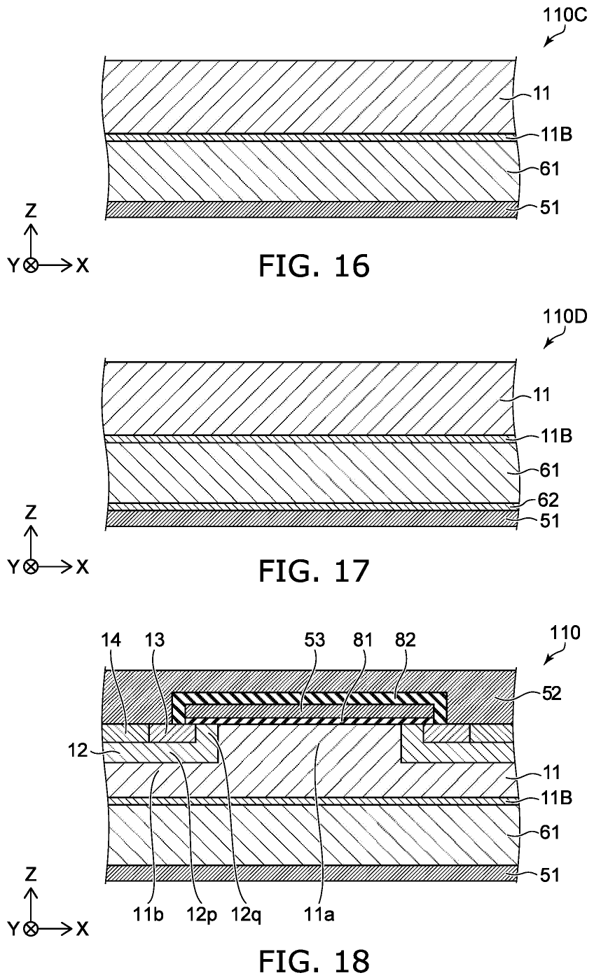

FIG. 16 is a schematic cross-sectional view illustrating the semiconductor device according to the fourth embodiment.

As shown in FIG. 16, a semiconductor device 110C according to the embodiment includes the first intermediate layer 61, the first layer 11, and the first electrode 51. The first intermediate layer 61 is the first intermediate layer after at least a part of the substrate 10s (see FIG. 1A and the like) has been removed. The electrode 51 is electrically connected with the first intermediate layer 61 obtained by removing at least a part of the substrate 10s of the wafer according to the first embodiment. In the semiconductor device 110C according to the embodiment, the stress is relaxed. In the first layer 11 of the semiconductor device 110C, for example, a low dislocation density can be obtained. A semiconductor device having good characteristics can be obtained.

FIG. 17 is a schematic cross-sectional view illustrating the semiconductor device according to the fourth embodiment.

As shown in FIG. 17, a semiconductor device 110D according to the embodiment includes the second intermediate layer 62, the first intermediate layer 61, the first layer 11, and the first electrode 51. The first intermediate layer 61 is electrically connected with the second intermediate layer 62. In this example, the first electrode 51 is electrically connected with the first intermediate layer 61 after at least a part of the substrate 10s has been removed via the second intermediate layer 62. In the semiconductor device 110D, the stress is relaxed. In the first layer 11, for example, a low dislocation density can be obtained. A semiconductor device having good characteristics can be obtained.

FIG. 18 is a schematic cross-sectional view illustrating the semiconductor device according to the fourth embodiment.

As shown in FIG. 18, the semiconductor device 110 according to the embodiment has the first intermediate layer 61, the first layer 11, the second semiconductor region 12, a third semiconductor region 13, the first electrode 51, a second electrode 52, a third electrode 53, and a first insulating member 81. The first layer 11 corresponds to an n-type first semiconductor region including nitrogen. The second semiconductor region corresponds to a p-type semiconductor region including the first element 69B. The third semiconductor region 13 corresponds to an n-type semiconductor region including nitrogen.

The first layer 11 includes a first partial region 11a and a second partial region 11b. A second direction from the second partial region 11b to the first partial region 11a crosses the first direction (Z-axis direction). The second direction is along the X-axis direction. A position of the second partial region 11b in the second direction is different from a position of the first partial region 11a in the second direction.

At least a part of the third semiconductor region 13 is provided between the second partial region 11b and a part of the third electrode 53 in the first direction (Z-axis direction). A part 12p of the second semiconductor region 12 is provided between the second partial region 11b and the third semiconductor region 13 in the first direction (Z-axis direction). In the second direction (X-axis direction), another part 12q of the second semiconductor region 12 is provided between the third semiconductor region 13 and a part of the first partial region 11a. The other part 12q of the second semiconductor region 12 is located between the second partial region 11b and a part of the third electrode 53 in the first direction (Z-axis direction).

In the first direction (Z-axis direction), the first insulating member 81 is located between the third semiconductor region 13 and the third electrode 53, between the other portion 12q of the second semiconductor region 12 and the third electrode 53, and between the first partial region 11a and the third electrode 53. The second electrode 52 is electrically connected with the third semiconductor region 13.

A current flowing between the first electrode 51 and the second electrode 52 can be controlled by a potential of the third electrode 53. The potential of the third electrode 53 may be, for example, a potential based on a potential of the second electrode 52. The first electrode 51 functions as, for example, a drain electrode. The second electrode 52 functions as, for example, a source electrode. The third electrode 53 functions as, for example, a gate electrode. The first insulating member 81 functions as a gate insulating film. The semiconductor device 110 is, for example, a transistor. The semiconductor device 110 is, for example, a MOS transistor.

In this example, a fourth semiconductor region 14 and a second insulating member 82 are provided. The fourth semiconductor region 14 includes the first element 69B. The fourth semiconductor region 14 corresponds to a p-type semiconductor region including the first element 69B. In the second direction (X-axis direction), the third semiconductor region 13 is between the fourth semiconductor region 14 and the other portion 12q of the second semiconductor region 12. The second electrode 52 is electrically connected with the fourth semiconductor region 14.

The second insulating member 82 is provided between the third electrode 53 and the second electrode 52. The second insulating member 82 electrically insulates the third electrode 53 from the second electrode 52.

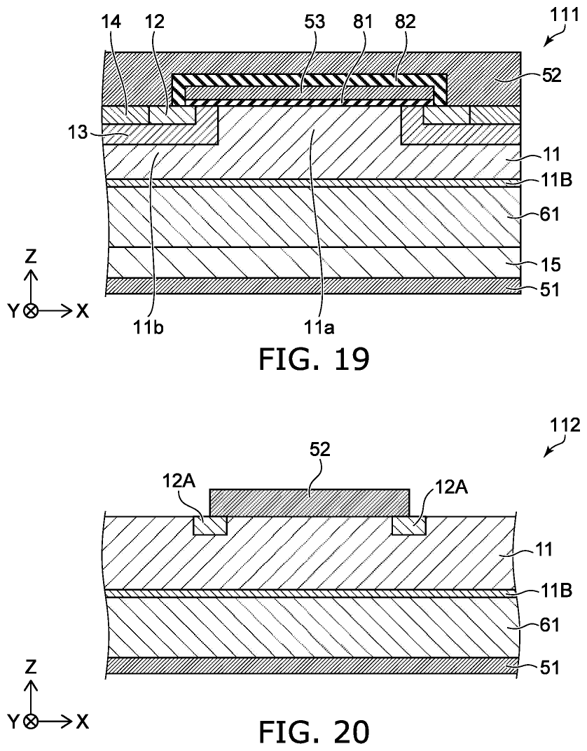

FIG. 19 is a schematic cross-sectional view illustrating a semiconductor device according to the fourth embodiment.

As shown in FIG. 19, a semiconductor device 111 according to the embodiment includes the first intermediate layer 61, the first layer 11, the second semiconductor region 12, the third semiconductor region 13, a fifth semiconductor region 15, the first electrode 51, the second electrode 52, the third electrode 53, and the first insulating member 81. In the semiconductor device 111, the first layer 11, the second semiconductor region 12, the third semiconductor region 13, the first electrode 51, the second electrode 52, the third electrode 53, and the first insulating member 81 may be the same as those in the semiconductor device 110.

The fifth semiconductor region 15 is provided between the first electrode 51 and the first intermediate layer 61. The fifth semiconductor region 15 corresponds to a p-type semiconductor region including the first element 69B. The semiconductor device 111 is, for example, an IGBT (Insulated Gate Bipolar Transistor).

FIG. 20 is a schematic cross-sectional view illustrating a semiconductor device according to the fourth embodiment.

As shown in FIG. 20, a semiconductor device 112 according to the embodiment includes the first intermediate layer 61, the first layer 11, the first electrode 51, and the second electrode 52. The first intermediate layer 61 is located between the first electrode 51 and the second electrode 52. The first layer 11 is located between the first intermediate layer 61 and the second electrode 52. The first electrode 51 is electrically connected with the first intermediate layer 61. The second electrode 52 is electrically connected with the first layer 11. The semiconductor device 112 is, for example, a Schottky diode.

As shown in FIG. 20, the semiconductor device 112 may include a terminate region 12A. The terminate region 12A is provided between the first layer 11 and an end of the second electrode 52. The terminate region 12A includes, for example, the first element 69B. The terminate region 12A corresponds to, for example, a p-type semiconductor region.

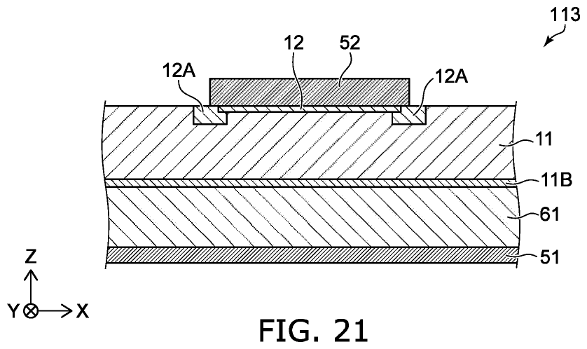

FIG. 21 is a schematic cross-sectional view illustrating a semiconductor device according to the fourth embodiment.

As shown in FIG. 21, a semiconductor device 113 according to the embodiment includes the first intermediate layer 61, the first layer 11, the second semiconductor region 12, the first electrode 51, and the second electrode 52. The first intermediate layer 61 is located between the first electrode 51 and the second electrode 52. The first layer 11 is between the first intermediate layer 61 and the second electrode 52. The second semiconductor region 12 is between the first layer 11 and the second electrode 52. The first electrode 51 is electrically connected with the first intermediate layer 61. The second electrode 52 is electrically connected with the second semiconductor region 12. The semiconductor device 113 is, for example, a p-n diode. The semiconductor device 113 may include the terminate region 12A.

In the semiconductor devices 110 to 113, stress is relaxed and stable characteristics can be obtained. For example, high electrical characteristics can be obtained.

In the semiconductor devices 110 to 113, the first electrode 51 includes, for example, Ni or Ni silicide. In the semiconductor devices 110, 111 and 113, the second electrode 52 includes, for example, at least one selected from the group consisting of Ni and Ti. In the semiconductor device 112, the second electrode 52 includes, for example, at least one selected from the group consisting of Ni and Ti/Al. In the semiconductor devices 110 to 113, the third electrode 53 includes, for example, at least one selected from the group consisting of Ni and amorphous Si.

According to the embodiment, it is possible to provide a wafer, a semiconductor device, a method for manufacturing the wafer, and a method for manufacturing the semiconductor device, which can improve the characteristics.

In the specification of the present application, the “electrically connected state” includes a state in which a plurality of conductors are physically in contact with each other and a current flows between the plurality of conductors. The “electrically connected state” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in wafer or semiconductor devices such as substrates, intermediate layers, first layers, semiconductor regions, electrodes, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all wafers, semiconductor devices, methods for manufacturing the wafer, and methods for manufacturing the semiconductor device practicable by an appropriate design modification by one skilled in the art based on the wafers, the semiconductor devices, the methods for manufacturing the wafer, and the methods for manufacturing the semiconductor device described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A wafer, comprising:
a substrate including a plurality of SiC regions including SiC and an inter-SiC region including Si provided between the SiC regions; and
a crystal layer including a first layer, and a first intermediate layer provided between the substrate and the first layer in a first direction, the first layer including SiC and nitrogen, the first intermediate layer including SiC and nitrogen, a second concentration of nitrogen in the first intermediate layer being higher than a first concentration of nitrogen in the first layer.

2. The wafer according to claim 1, wherein the second concentration is not less than 5 times the first concentration.

3. The wafer according to claim 1, wherein
the first concentration is not less than 1×10¹⁵ cm⁻³ and not more than 2×10¹⁷ cm⁻³, and
the second concentration is not less than 1×10¹⁸ cm⁻³ and not more than 5×10¹⁹ cm⁻³.

4. The wafer according to claim 1, wherein a first thickness of the first layer along the first direction is not less than 0.2 times and not more than 2 times a second thickness of the first intermediate layer along the first direction.

5. The wafer according to claim 1, wherein a first thickness of the first layer along the first direction is not less than 10 μm and not more than 80 μm.

6. The wafer according to claim 1, wherein a thickness of the first intermediate layer along the first direction is not less than 20 μm and not more than 80 μm.

7. The wafer according to claim 1, wherein a third thickness of the substrate along the first direction is not less than 4 times a thickness of the crystal layer along the first direction.

8. The wafer according to claim 1, wherein the substrate includes a plurality of the inter-SiC regions, and
an average length of the inter-SiC regions along a direction perpendicular to the first direction is not more than 0.3 μm.

9. The wafer according to claim 1, wherein an angle between a (11-21) plane in the first layer and a plane perpendicular to a direction from the first intermediate layer to the first layer is not more than 4.5 degrees.

10. The wafer according to claim 1, wherein a basal plane dislocation density in the first intermediate layer is higher than a basal plane dislocation density in the first layer.

11. The wafer according to claim 1, further comprising: a second intermediate layer provided between the substrate and the first intermediate layer and including SiC,
a concentration of nitrogen in the second intermediate layer is higher than the second concentration.

12. A semiconductor device, comprising:
a first electrode electrically connected with the first intermediate layer obtained by removing at least a part of the substrate of the wafer according to claim 1;
the first intermediate layer obtained by the removing the at least the part of the substrate; and
the first layer.

13. A method for manufacturing a wafer, comprising:
forming a first layer including SiC and nitrogen on a first intermediate layer base body to be a first intermediate layer including SiC and nitrogen, a second concentration of nitrogen in the first intermediate layer base body being higher than a first concentration of nitrogen in the first layer, the first intermediate layer base body including a first layered region and a second layered region, the first layered region being between the second layered region and the first layer;
removing the second layered region; and
bonding a remaining first layered region to a substrate, the substrate including a plurality of SiC regions including SiC, and an inter-SiC region including Si provided between the SiC regions.

14. The method according to claim 13, wherein
the removing the second layered region includes forming a third layered region between the first layered region and the second layered region after the forming the first layer, and
a crystallinity in the third layered region is lower than a crystallinity in the first layered region and lower than a crystallinity in the second layered region.

15. The method according to claim 14, wherein the forming the third layered region includes irradiating the first intermediate layer base body with an electromagnetic wave to form the third layered region.

16. The method according to claim 13, further comprising:
removing a part of the remaining first layered region and flattening after the removing the second layered region and prior to the bonding.

17. The method according to claim 13, further comprising:
polishing the substrate with a plurality of abrasive grains prior to the bonding of the substrates,
an average diameter of the abrasive grains being not less than 0.5 μm.

18. The method according to claim 13, wherein
the substrate includes a first substrate portion and a second substrate portion,
the first substrate portion includes a plurality of SiC regions including SiC, and an inter-SiC region including Si provided between the SiC regions,
the second substrate portion is provided on a surface of the first substrate portion,
the second substrate portion includes polycrystalline SiC, and
a concentration of nitrogen in the second substrate portion is higher than the second concentration.

19. A method for manufacturing a semiconductor device, comprising:
introducing a first element into at least a part of the first layer of the wafer according to claim 1, the first element including at least one selected from the group consisting of B, Al and Ga; and
performing a heat treatment at a temperature not less than 1600° C. after the introducing.

20. The method according to claim 19, further comprising:
removing at least a part of the substrate after the heat treatment; and
forming a first electrode on a surface of the substrate exposed by the removing the at least the part of the substrate.

21. The method according to claim 19, further comprising:
removing a part of the substrate and remaining an other part of the substrate after the heat treatment; and
forming a first electrode on a surface of the substrate exposed by the removing the part of the substrate.
